(19) United States
(12) Patent Application Publication
(10) Pub. No.: US 2012/0152329 A1
(43) Pub. Date: Jun. 21, 2012

(54) SOLAR CELL MODULE

(75) Inventors: Masayuki Aou, Kaizuka-shi (JP); Shihomi Nakatani, Kaizuka-shi (JP)

(73) Assignee: SANYO ELECTRIC CO., LTD., Moriguchi-shi (JP)

(21) Appl. No.: 13/393,129

(22) PCT Filed: Aug. 30, 2010
(86) PCT No.: PCT/JP2010/064677

§ 371 Date: Feb. 28, 2012

(30) Foreign Application Priority Data
Aug. 31, 2009 (JP) 2009-200470

(51) Int. Cl. H01L 31/048

(52) U.S. Cl. 136/251

(57) ABSTRACT

An object of the present invention is to reduce adverse affect of moisture passing through the opening, for improved reliability and product yield of solar cell module. A solar cell module includes: a front-surface protection member; a rear-surface protection member; a plurality of solar cells 11 electrically connected by wiring members; a bonding member for encapsulating the solar cells between the front-surface protection member and the rear-surface protection member; and power output wires for taking an output from the solar cells. The rear-surface protection member has an opening at a location facing a surface of one solar cell, and the power output wires are routed out of the rear-surface protection member through the opening.

### TECHNICAL FIELD

The present invention relates to solar cell modules.

### BACKGROUND ART

Solar cells are expected to be a new energy source due to their ability to convert inexhaustible supply of sunlight directly into electricity.

Generally, a single solar cell can supply an output of only a few watts. For this reason, when solar cell is utilized as a power source for a house, a building, etc., a plurality of solar cells are connected together in the form of a solar cell module for increased output. The solar cell module includes a plurality of solar cells each having a front and a rear surfaces provided with electrodes, via which they are connected in series and/or parallel by wiring members.

The solar cells which are mutually connected via the wiring members are placed between a transparent front-surface protection member and a rear-surface protection member, being sealed in a encapsulant composed mainly of ethylene vinyl acetate copolymer (EVA) for example, for increased resistance to weathering and impacts so that practical tapping of electrical power can be possible in outdoor environment.

FIG. 17 is a schematic sectional view of a conventional solar cell module. This solar cell module includes a transparent front-surface protection member 301 made of glass for example; solar cells 303; transparent bonding members 302, 304; and a rear-surface protection member 305.

In this solar cell module, each of the solar cells 303 has electrodes on their front and rear surfaces. These solar cells are connected together by inner lead wires 306, sandwiched between the front-surface protection member 301 and the rear-surface protection member 305, and encapsulated by the transparent bonding members 302, 304.

Since the output from the solar cells must be taken out of the solar cell module, openings 305b, 304b are provided as shown in FIG. 17, in the rear-surface protection member 305 and in the rear-surface-side bonding member 304 respectively. From these openings 305b, 304b, power output wires (lead-out electrodes) 307 which are connected to the solar cells 303 are routed out to the outside. Although not illustrated, a terminal box is attached to the opening 305b, so that the power output wires 307 from the opening 305b can be connected to terminals provided inside the terminal box for further connection to an external circuit (see Patent Literature 1, FIG. 4, for example).

In a solar cell module disclosed in the Patent Literature 1, the rear-surface-side bonding member 304 and the rear-surface protection member 305 are respectively provided with the openings 304b, 305b which have a size, for example, of 40 mm×70 mm in order to expose ends of the power output wires 307. In addition, a bonding member 309 is disposed between the solar cell 303 and the power output wires 307. The bonding member 309 is a laminated body which is composed of an adhering member 310 and a moistureproof member 311, made sufficiently larger than the openings 304b, 305b in the rear-surface-side bonding member 304 and the rear-surface protection member 305, and disposed between the power output wires 307 and the solar cell 303.

After all of these components have been disposed and stacked as described above, the solar cell module is placed in a laminator, so that the entire assembly is pressed together into an integrated body under a heat and a reduced pressure. The integration process leaves end portions of the power output wires 307 exposed in the openings 304b, 305b in the rear-surface-side bonding member 304 and the rear-surface protection member 305. Therefore, the end portions of the power output wires 307 may be bent out when it is necessary, whereby the power output wires 307 can be led out of the openings 304b, 305b very easily as shown in FIG. 17.

Further, since the openings 304b, 305b are sealed by the bonding member 309 provided by a laminated body composed of the adhering member 310 and the moistureproof member 311, moisture for example, is prevented from passing through the openings into the solar cell module and degrading power output capability of the solar cell module. Therefore a good level of reliability is maintained.

### CITATION LIST

### Patent Literature

[Patent Literature 1] JP-A 2004-356349 Gazette (FIG. 4)

### SUMMARY OF INVENTION

### Technical Problem

Patent Literature 1 gives no consideration to the location at which the openings 304b, 305b are made.

The power output wires 307 must be provided at an appropriate spacing from one power output wire 307 to the next for example, since they must come out of the openings 304b, 305b and since there is the terminal box attached therearound. Also, moisture will eventually enter from the openings 304b, 305b, so some preventative means should be provided to deal with moisture-caused performance deterioration. Location of the openings will also influence performance and product yield.

It is an object of the present invention to reduce adverse affect of moisture entry through the opening, for improved reliability and product yield of the solar cell module.

### Solution to Problem

The present invention provides a solar cell module which includes: a front-surface protection member; a rear-surface protection member; a plurality of solar cells electrically connected by wiring members and disposed between the front-surface protection member and the rear-surface protection member; a bonding member for encapsulating the solar cells between the front-surface protection member and the rear-surface protection member; and output wires for taking an output from the solar cells. With the arrangement described above, the rear-surface protection member has an opening at a location facing a surface of one of the solar cells, and the power output wires are routed out of the rear-surface protection member through this opening.

Also, the present invention provides an arrangement that a sealing film is disposed in a manner to cover the opening. The sealing film has a slit for insertion of the power output wires, and the power output wires are routed out of the rear-surface protection member through the slit in the sealing film and the opening.

Also, a terminal box may be attached to the rear-surface protection member to cover the opening in the rear-surface protection member.

### Advantageous Effects of Invention

According to the present invention, the opening in the rear-surface protection member is faced by a rear surface of one solar cell, and therefore risks from the opening is limited only to one solar cell, and therefore the arrangement can minimize influence on the performance decrease.

### BRIEF DESCRIPTION OF THE DRAWINGS

FIG. 1 is a schematic sectional view of a solar cell module according to an embodiment of the present invention.

FIG. 2 is a schematic sectional view showing a configuration of a solar cell utilized in the present invention.

FIG. 3 is a schematic diagram of a manufacturing apparatus for manufacture of a solar cell module.

FIG. 4 is a fragmentary sectional view showing a power output wire lead-out region in the embodiment of the present invention before a laminating step.

FIG. 5 is a fragmentary sectional view showing a power output wire lead-out region in the embodiment of the present invention after the laminating step.

FIG. 6 is a plan view showing an opening in the solar cell module according the embodiment of the present invention.

FIG. 7 is a plan view when a power output wire region in a solar cell module according to a first embodiment of the present invention is viewed from rear.

FIG. 8 is a sectional view taken in a line A1-A1 in FIG. 7.

FIG. 9 is a sectional view taken in a line A2-A2 in FIG. 7.

FIG. 10 is a plan view when a power output wire region in a solar cell module according to a second embodiment of the present invention is viewed from rear.

FIG. 11 is a sectional view taken in a line B2-B2 in FIG. 10.

FIG. 12 is a sectional view taken in a line B1-B1 in FIG. 10.

FIG. 13 is a plan view when a power output wire region in a solar cell module according to a third embodiment of the present invention is viewed from rear.

FIG. 14 is a plan view when a power output wire region in a solar cell module according to a fourth embodiment of the present invention is viewed from rear.

FIG. 15 is a plan view when a power output wire region in a solar cell module according to a fifth embodiment of the present invention is viewed from rear.

FIG. 16 is a fragmentary sectional view showing a power output wire lead-out region of another embodiment of the present invention after the laminating step.

FIG. 17 is a schematic sectional view of a conventional solar cell module.

### DESCRIPTION OF EMBODIMENTS

Embodiments of the present invention will be described in detail with reference to the drawings. It should be noted here that throughout the drawings the same or equivalent parts and components will be indicated with the same reference symbols, and their description will not be repeated in order to avoid redundancy in description. It should also be noted that all the drawings are of a conceptual nature and may not reflect actual dimensional proportions, etc. Therefore, information about specific dimensions, etc. should be understood and determined from the description to be given hereafter. Keep in mind that proportional and other relationships may also differ from one drawing to another.

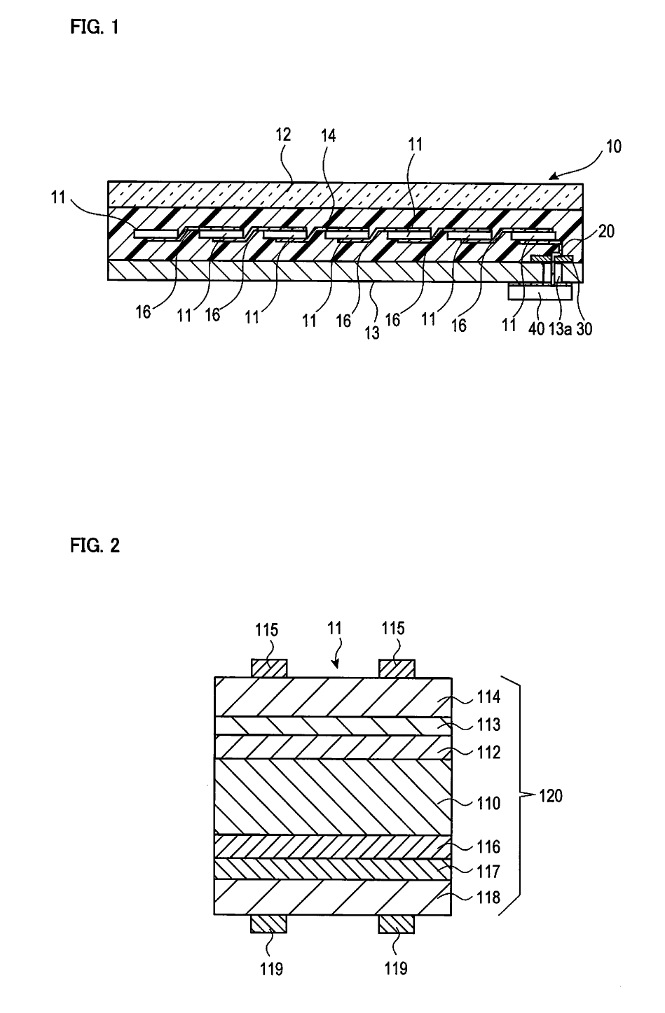

Now, reference will be made to FIG. 1 to describe general configuration of a solar cell module 10 according to an embodiment of the present invention. FIG. 1 is an enlarged side view showing a section of the solar cell module 10 according to the present embodiment.

The solar cell module 10 includes solar cells 11, a front-surface protection member 12, a rear-surface protection member 13 and a bonding member 14. The solar cell module 10 is made by encapsulating a plurality of the solar cells 11 between the front-surface protection member 12 and the rear-surface protection member 13.

The solar cells 11 are connected with each other by wiring members 16. The connection between the solar cell 11 and the wiring member 16 is achieved by solder or resin adhesive.

Each solar cell 11 has a light receiving surface for sunlight incident, and a rear surface facing away from the light receiving surface. Each solar cell 11 has electrodes formed on its light receiving surface and its rear surface. The solar cell 11 has a configuration, which will be described later in more detail.

The wiring member 16 is connected to the electrode on the light receiving surface of one solar cell 11 and to the electrode on the rear surface of another solar cell 11 which is adjacent thereto. Thus, electrical connection is established between mutually adjacent solar cells 11, 11. The wiring member 16 is a thin platy piece of copper foil having its surfaces plated with solder.

If the wiring member 16 and the solar cell 11 are connected to each other with solder, the solder which is plated on the wiring member 16 is caused to melt to connect to the electrode on the solar cell 11.

If resin adhesive is used, a resin adhesive is applied between the wiring member 16 and the solar cell 11, so that the solar cell 11 and the wiring member 16 are connected to each other via the resin adhesive. It is preferable that the resin adhesive sets at temperatures not higher than the melting temperature of eutectic solder, i.e., approximately 200° C. The resin adhesive may be provided by an electrically conductive adhesive film for example. The electrically conductive adhesive film should at least contain a resin adhesive component and electrically conductive particles dispersed therein. This resin adhesive component containing the above-mentioned electrically conductive particles therein is provided on a backing film of polyimide for example. The resin adhesive component is a composition containing a thermosetting resin, and may be provided by epoxy resin, phenoxy resin, acrylic resin, polyimide resin, polyamide resin or polycarbonate resin. Only one kind may be selected from these thermosetting resins, or a combination of two or more kinds may be used. Preferably, one or more thermosetting resins selected from a group consisting of epoxy resin, phenoxy resin and acrylic resin should be utilized.

The electrically conductive particles may be provided by particles of a metal such as gold, silver, copper and nickel, or particles of an electrically conductive or insulating material having their surfaces coated with an electrically conductive layer of gold, copper, nickel or others.

The front-surface protection member 12 is disposed on the light receiving surface side of the bonding member 14 and protects the surface of solar cell module 10. The front-surface protection member 12 may be provided by water-shielding transparent glass, transparent plastic, etc.

The rear-surface protection member 13 is disposed on the rear surface side of the bonding member 14 and protects the rear surface of the solar cell module 10. The rear-surface protection member 13 may be provided by a film of a resin such as PET (Polyethylene Terephthalate), or a laminated film made by sandwiching a foil of Al between resin films. In the present embodiment shown in FIG. 1, the rear-surface protection member 13 is provided by a resin film of PET for example.

The bonding member 14 encapsulates the solar cells 11 between the front-surface protection member 12 and the rear-surface protection member 13. The bonding member 14 may be provided by a transparent resin such as EVA, EEA, PVB, silicone, urethane, acrylic and epoxy. In the present embodiment, an EVA resin.

It should be noted here that the solar cell module 10 configured as the above may have an Al (aluminum) frame (unillustrated) attached therearound.

The wiring members 16 are connected to power output wires 20 for taking the solar cells' output to the outside of the module. The power output wires 20 serve as a route to carry the electrical output from the solar cells 11 to terminals in a terminal box 40, and are normally provided by a piece obtained by solder-plating an entire surface of a copper foil which has a thickness of approximately 0.1 mm through 0.3 mm and a width of 6 mm and cutting this foil into a predetermined length. The wire thus obtained is soldered to the wiring member 16. The power output wire 20 has its surfaces coated with an insulating film 20a.

The rear-surface protection member 13 has an opening 13a for the power output wires 20 to come out. As will be described later, this opening 13a in the rear-surface protection member 13 is made at a location facing a surface of one solar cell 11. As will be described later also, the bonding member 14 on the rear surface side has an opening for the power output wires 20 to come out, too. These openings are rectangular, having a size of 40 mm×70 mm for example.

The present embodiment includes a sealing film 30 which is sufficiently larger than these openings. As will be described later, this sealing film 30 has a slit for the power output wires 20 to be inserted therethrough. This slit is only slightly wider than the thickness of the power output wires 20, and is long enough for insertion of a plurality of the power output wires 20. As the power output wires 20 are inserted into the slit in the sealing film 30, the spacing, the length, etc. of the power output wires 20 are determined accordingly.

The sealing film 30 disposed to cover the opening 13a sets the power output wires 20 to come out of the rear-surface protection member 13 in the solar cell module 10 by predetermined length and spacing. Further, the sealing film 30 prevents moisture entry from the opening 13a.

The terminal box 40 is attached using a silicone resin for example, to cover the opening 13a in the rear-surface protection member 13. The power output wires 20 coming out of the opening 13a are then connected to the terminals in the terminal box 40 for connection to an external circuit.

Next, a configuration of the solar cells 11 will be described.

The solar cell 11 has a photoelectric conversion section and electrodes. The electrodes are, for example, finger electrodes and busbar electrodes.

The photoelectric conversion section produces carriers as it receives sunlight. In this Description, the term carriers refers to positive holes and electrons produced by the sunlight as it is absorbed in the photoelectric conversion section. The photoelectric conversion section has an n-type region and a p-type region therein, with a semiconductor junction formed in the interface between the n-type region and the p-type region. The photoelectric conversion section may be formed from a semiconductor substrate of a crystalline semiconductor material such as monocrystalline Si and polycrystalline Si; a semiconductor compound such as GaAs and InP; etc. The photoelectric conversion section in the solar cell utilizes an arrangement, for example, where an intrinsic amorphous silicon layer is placed between a monocrystalline silicon layer and an amorphous silicon layer of mutually opposing conductivity types for reduced defect in the interface and improved characteristic of hetero junction interface.

The finger electrodes collect carriers from the photoelectric conversion section. The finger electrodes are formed to cover substantially all of the light receiving surface in the photoelectric conversion section. The finger electrodes may be formed by using an electrically conductive resin paste made of a resin material as a binder and electrically conductive particles of e.g. silver as a filler. It should be noted here that the finger electrodes are formed both on the light receiving surface and on the rear surface of the photoelectric conversion section alike.

The busbar electrodes collect carriers from the finger electrodes. The busbar electrodes are formed to cross the finger electrodes. The busbar electrode may be formed by substantially the same method as for the finger electrodes, by using an electrically conductive resin paste made of a resin material as a binder and electrically conductive particles of e.g. silver as a filler.

The quantity of the busbar electrodes may be determined in consideration of the size of the photoelectric conversion section for example.

Next, as a specific configuration example of the solar cell 10, description will cover a case where the photoelectric conversion section has a structure called Heterojunction with Intrinsic Thin-layer, with a reference to FIG. 2. FIG. 2 is a schematic sectional view showing the configuration of the solar cell.

As shown in FIG. 2, a photoelectric conversion section 120 includes a transparent conductive film 114, a p-type amorphous silicon layer 113, an i-type amorphous silicon layer 112, an n-type monocrystalline silicon substrate 110, an i-type amorphous silicon layer 116, an n-type amorphous silicon layer 117 and a transparent conductive film 118.

The n-type monocrystalline silicon substrate 110 has its light receiving surface side formed with the p-type amorphous silicon layer 113 via the i-type amorphous silicon layer 112. The p-type amorphous silicon layer 113 has its light receiving surface side formed with the transparent conductive film 114. On the other hand, the n-type monocrystalline silicon substrate 110 has its rear surface side formed with the n-type amorphous silicon layer 117 via the i-type amorphous silicon layer 116. The n-type amorphous silicon layer 117 has its rear surface side formed with the transparent conductive film 118.

Electrodes 115, 119 including finger electrodes and the busbar electrodes, are formed on the light receiving surface side of the transparent conductive film 114 and on the rear surface side of the transparent conductive film 118 respectively.

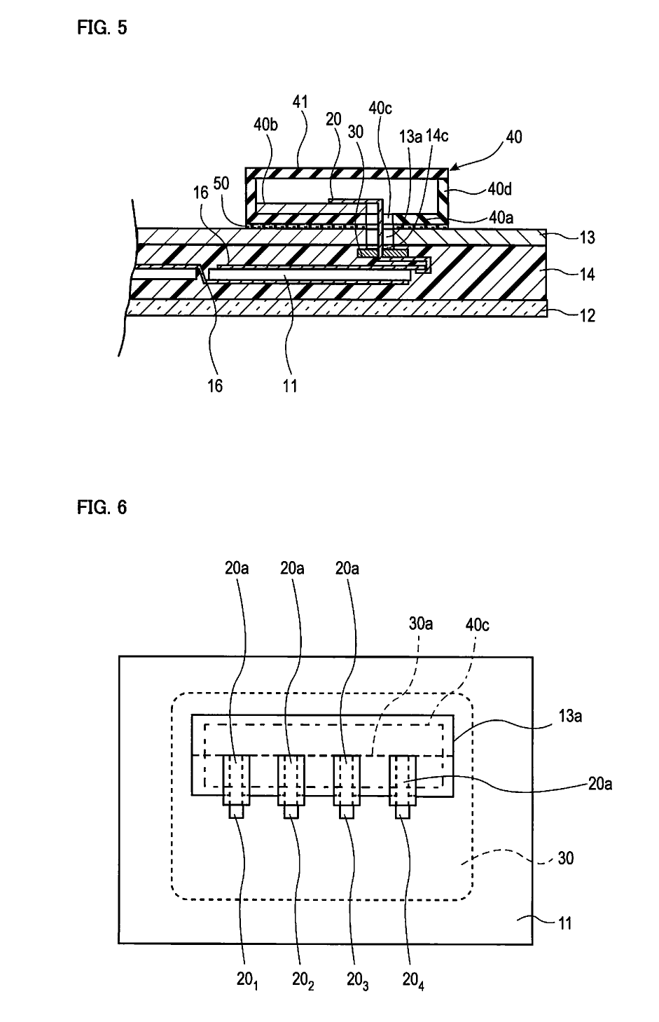

Hereinafter, reference will be made to FIG. 4 and FIG. 5 to describe how the power output wires 20 may be brought out of the solar cell module. FIG. 4 is a fragmentary sectional view showing a power output wire lead-out region of the present embodiment before a laminating step whereas FIG. 5 shows the power output wire lead-out region of the present embodiment after the laminating step.

As shown in FIG. 4 and FIG. 5, openings 14c, 13a are made in the rear surface side bonding member 14b and the rear-surface protection member 13 respectively. These openings 14c, 13a are completely covered by the sealing film 30 which has the slit 30a for insertion of the power output wires 20 and is disposed between the rear surface side bonding member 14b and a solar cell 11. The sealing film 30 is a film of a resin such as PET and PVF.

The power output wires 20 are inserted through the slit 30a of the sealing film 30. The sealing film 30 is disposed between the rear-surface protection member 13 and the solar cell 11. This slit 30a is only slightly wider than the thickness of the power output wires 20, and is long enough for insertion of a plurality of the power output wires 20 side by side. As the power output wires 20 are inserted into the slit 30a in the sealing film 30, spacing between the power output wires 20, the length by which each wire can be pulled out, etc. are determined accordingly.

The sealing film 30 disposed to cover the openings 13a, 14c, sets the power output wires 20 to come out of the rear-surface protection member 13 in the solar cell module 10 by predetermined length and spacing.

The sealing film 30 is first tentatively fixed so as to cover the opening 14c in the rear surface side bonding member 14b, and then the power output wires 20 are inserted through the slit 30a. This procedure prevents undesirable movement of the sealing film 30 during a step of modularization, resulting in improved assemblability.

After the laminating step, the sealing film 30 is at the openings 13a, 14c as shown in FIG. 5. The sealing film 30 is introduced also into these openings 13a, 14c, establishing water-tight sealing to the openings 13a, 14c. Then, the terminal box 40 has its bottom 40a bonded around the opening 13a in the rear-surface protection member 13 using a silicone resin 50 for example. The bottom 40a of the terminal box 40 has an opening 40c for insertion of the power output wires 20. This opening 40c is smaller than the openings 13a, 14c. Also, the bottom 40a is larger than the opening 13a, 14c so as to provide complete coverage over the openings 13a, 14c. Specifically, the openings 13a, 14c are larger than the opening 40c of the terminal box 40, and smaller than the terminal box 40.

The power output wires 20 coming out of the openings 13a, 14c and the opening 40c are then connected to terminals on a terminal block 40b inside the terminal box 40. Thereafter, the terminal box 40 is sealingly closed by an upper lid 41 attached to a body 40c which is a continuous part from the bottom 40a, whereby the solar cell module 10 is complete.

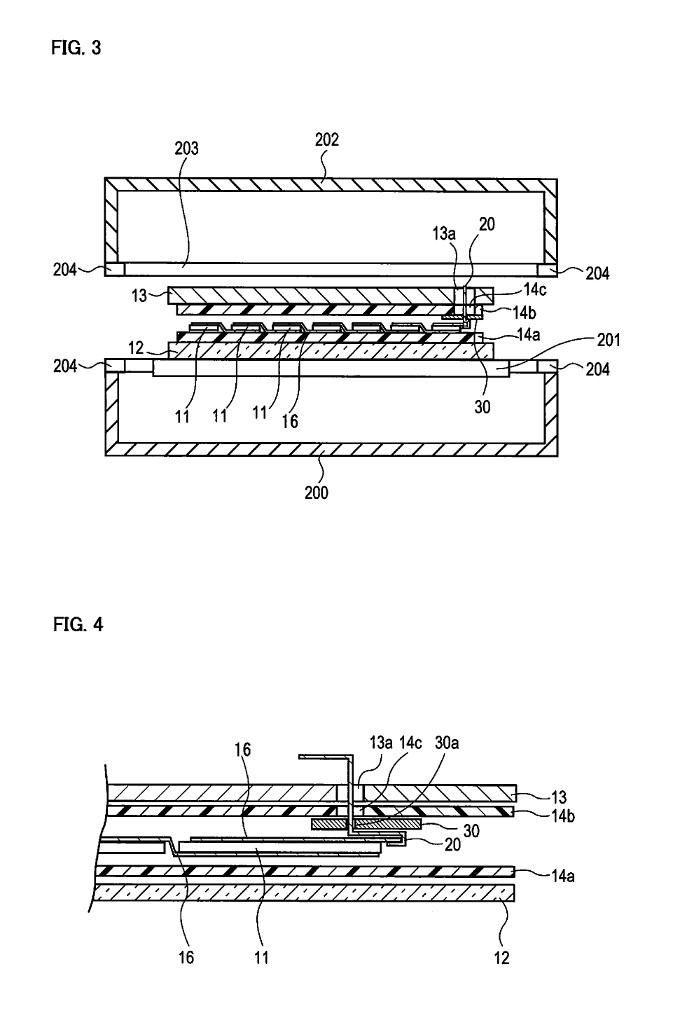

Next, a method of manufacturing the solar cell module 10 will be described with reference to FIG. 3. FIG. 3 is a schematic diagram of a manufacturing apparatus for manufacture of the solar cell module 10. The apparatus includes a lower housing 200 and an upper housing 202 to be coupled with the lower housing airtightly. The lower housing 200 has an upper opening, where a heater plate 201 is disposed substantially flush therewith. The upper housing 202 is provided with a rubber diaphragm 203 on a side opposed to the opening in the lower housing 200. The lower housing 200 and the upper housing 202 are provided with packings 204 entirely along their respective surrounding edges to maintain an air-tight state when the two housings are coupled together.

Further, though not illustrated, a vacuum pump is connected to the lower housing 200.

When manufacturing the solar cell module 10, first, the following components are placed on the heater plate 201 of the apparatus one after another in the order of listing: an front-surface protection member 12; a front surface side EVA sheet 14a (bonding member); a plurality of solar cells 11 . . . which are connected to each other with wiring members 16; a sealing film 30 at a place corresponding to an opening 14c in an EVA sheet 14b; the EVA sheet 14b (bonding member); and a rear-surface protection member 13. Power output wires 20 are inserted through the slit 30a in the sealing film 30, each of the power output wires 20 being tentatively held at its predetermined position.

After all of the above-mentioned components are laminated on the heater plate 201, the lower housing 200 and the upper housing 202 are coupled with each other. Thereafter, air in the lower housing 200 is removed by the unillustrated vacuum pump. During this process, the heater plate 201 is brought to a temperature range of approximately 130° C. through 200° C. Under this state, the diaphragm 203 is pressed down toward the solar cell module 10 which is placed on the heater plate 201. The EVA sheets 14a, 14b gelate to become a predetermined EVA layer (bonding layer) 14. Through this process, the solar cells 11 . . . , which are already sandwiched between the front-surface protection member 12 on the front surface side and the rear-surface protection member 13 on the rear surface side, are sealed into the EVA layer (bonding layer) 14. Meanwhile, the sealing film 30 flows into and fills the opening 14c in the EVA sheet 14b integrally therewith, thereby closing the opening 14c.

Thereafter, a terminal box 40 is attached to the rear-surface protection member 13 with a silicone resin 50, to close the opening 13a in the rear-surface protection member 13.

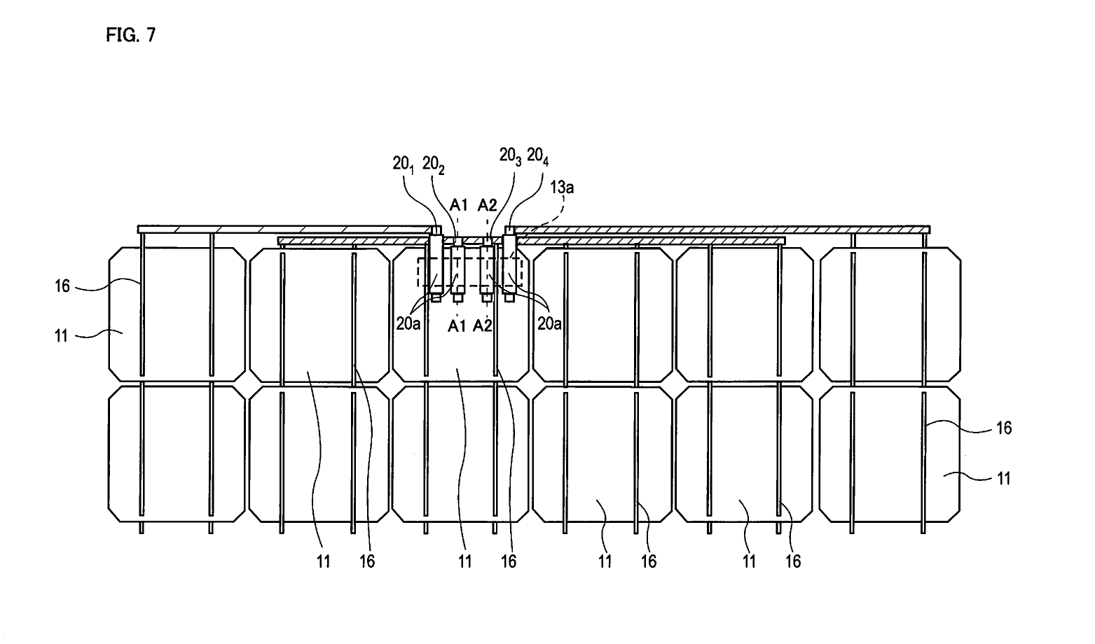

FIG. 6 is a plan view showing the power output wires and the opening in the solar cell module according to the present embodiment whereas FIG. 7 is a plan view when power output wires 20₁ through 20₄ in the solar cell module according to the present embodiment is viewed from the rear surface side.

As shown in FIG. 6 and FIG. 7, in the embodiment according to the present invention, the opening 13a in the rear-surface protection member 13 is located at a place faced by a surface of one solar cell 11. The place where the rear-surface protection member 13 has the opening 13a is the place where the sealing film 30 is disposed. Thus, the sealing film 30 reduces moisture entering from the opening 13a. Moisture which has found its way through the opening 13a will reach the rear surface side of this solar cell 11. Thus, moisture-caused performance decrease in the solar cells 11 is limited to only one solar cell 11. The invention can minimize consequential performance decrease in the solar cell module 10.

Also, since the opening 13a does not face any gap between two solar cells 11, 11, the invention can enhance prevention of moisture entry from between the solar cells 11, 11 toward the front surface side thereof. A typical problem especially in cases where the front-surface protection member 12 is provided by glass and the solar cells 11 are provided by a type so called Heterojunction with Intrinsic Thin-layer structure, is that moisture on the front surface side will allow impurities from the glass to deteriorate characteristics of the amorphous layers. In the present embodiment, an opening 13a is made to face a rear surface of one solar cell 11. This arrangement reduces the problem of moisture finding its way through gaps between the solar cells 11, 11 to the front surface side, and thereby reduces the problem of performance decrease in the solar cells 11.

In the present embodiment, a total of four power output wires are routed of the opening 13a through the slit 30a in the sealing film 30. Accordingly, the terminal block of the terminal box 40 is provided with four terminals, for connection of power output wires 20₁ through 20₄. Each of the terminals in the terminal box 40 is connected to a back flow preventing diode. Each of these power output wires 20₁ through 20₄ is insulated from the other power output wires by an insulation film 20a. In the present embodiment, the power output wires 20₁, 20₄ are connected respectively to a positive terminal and a negative terminal for connection to external lead wires. The power output wires 20₂, 20₃ constitute so called transition wiring between solar cell strings, with part of the wires being routed to the terminals in the terminal box 40.

In FIG. 7, a total of six solar cell strings are connected in series. The leftmost solar cell string has the power output wire 20₁, which comes out of the slit 30a in the sealing film 30, and is connected to the positive or negative terminal in the terminal box 40 for connection to an external lead wire. The second and the third solar cell strings from the left are connected to each other with a transition output wire 20₂. This output wire 20₂ comes out of the slit 30a in the sealing film 30, and is connected to the terminal in the terminal box 40. The second and the third solar cell strings from the right are connected to each other with a transition output wire 20₃. This output wire 20₃ comes out of the slit 30a in the sealing film 30, and is connected to the terminal in the terminal box 40. The rightmost solar cell string has the power output wire 20₄, which comes out of the slit 30a in the sealing film 30, and is connected to the negative or positive terminal in the terminal box 40 for connection to the external lead wire.

As has been described, the power output wires 20₁ through 20₄ are started from six solar cell strings, then routed through the opening 13a in the rear-surface protection member 13, and then connected to predetermined terminals in the terminal box 40, to constitute a solar cell module. Typically, power output wires 20 are stacked one after another. This means that the overall thickness will increase each time a wire connection is made. If the thickness keeps growing, it is likely that the stacked wires will tear the rear-surface protection member 13 in the solar cell module during the laminating step. For this reason, it is preferable that the overall thickness is small.

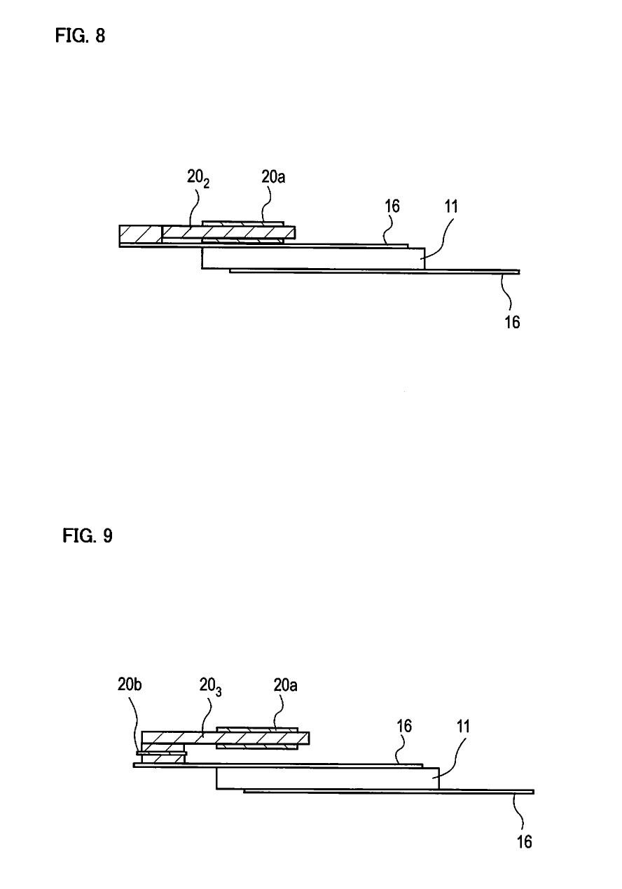

FIG. 8 is a sectional view taken in a line A1-A1 in FIG. 7 whereas FIG. 9 is a sectional view taken in a line A2-A2 in FIG. 7, to show sections of power output wiring at terminal regions. The wire connections in FIG. 7 through FIG. 9 are made sequentially by placing one component on another. Specifically, the power output wire 20₂ serves as a transition wire to connect the second and the third solar cell strings from the left, and part of this wire is extended as a lead. Since there are no other wires below this wire, the thickness is not very large as understood from FIG. 8. On the contrary, the power output wire 20₃ serves as a transition wire to connect the second and the third solar cell strings from the right, and part of this wire is extended as a lead. This wiring is made as a next step after the power output wire 20₂. In other words, the power output wire 20₂ is placed on the rear surface side of the solar cell 11 first, and the power output wire 20₃ is placed thereon. As shown in FIG. 9, the thickness will be large if the power output wire 20 is placed on the wiring member 16 which is connected on the rear surface side of the solar cell 11. It should be noted here that FIG. 9 shows that an insulation sheet 20b is inserted between two power output wires which are tiered one after the other.

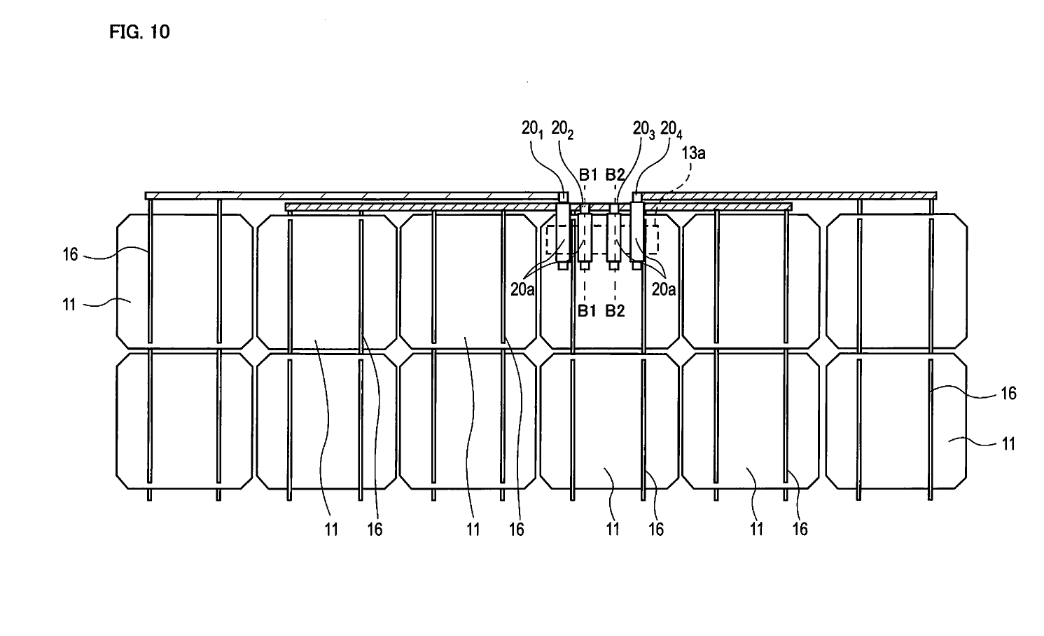

Now, the thickness can be reduced if the power output wires 20 are arranged as shown in FIG. 10 through FIG. 12.

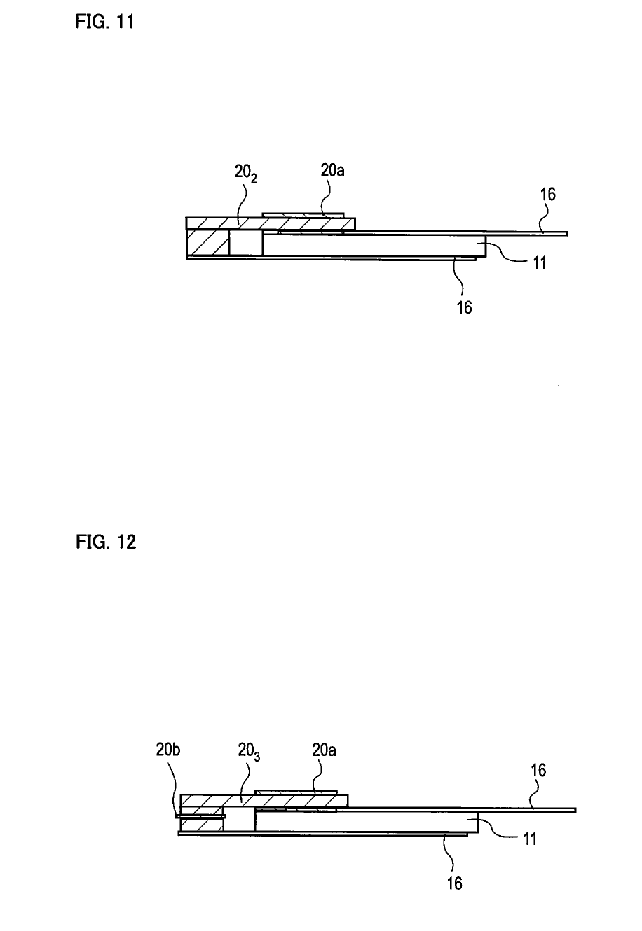

In this method of connection, a wiring member 16 which is connected to the light receiving surface side of a solar cell 11 is connected to another wiring member 16 which is connected to the rear surface side of an adjacent solar cell 11 via a power output wire. This wiring connects the solar cell strings. Then, the wire is routed out of the slit 30a of the sealing film 30, from a side closer to the solar cell 11 which has the wiring member 16 on its rear surface side. Then, the wire is pulled into the terminal box 40. FIG. 10 is a plan view when the power output wires 20₁ through 20₄ according to the above-described wiring method are viewed from the rear surface side, in a solar cell module according to a second embodiment of the present invention. FIG. 11 is a sectional view taken in a line B2-B2 in FIG. 10 whereas and FIG. 12 is a sectional view taken in a line B1-B1 in FIG. 10, to show sections of power output wires at the terminal. As will be clear from FIG. 8 and FIG. 11, FIG. 9 and FIG. 12, the present arrangement, that the power output wire is connected to the wiring member 16 which is provided on the light receiving surface side of the solar cell 11, can reduce the overall thickness because an amount of thickness of the wiring comes within the thickness of the solar cell 11.

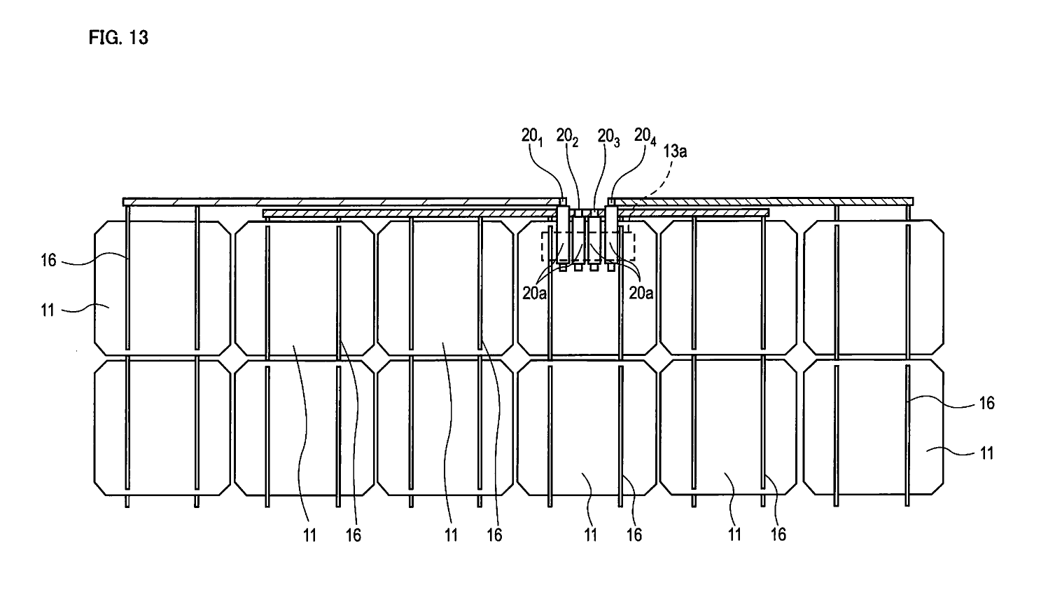

FIG. 13 is a plan view when the power output wires 20₁ through 20₄ in a solar cell module according to a third embodiment of the present invention which utilizes the above-described method are viewed from rear. According to the embodiment shown in this figure, the power output wires 20₁ through 20₄ are disposed between wiring members 16, 16. This arrangement enables size reduction of the terminal box 40.

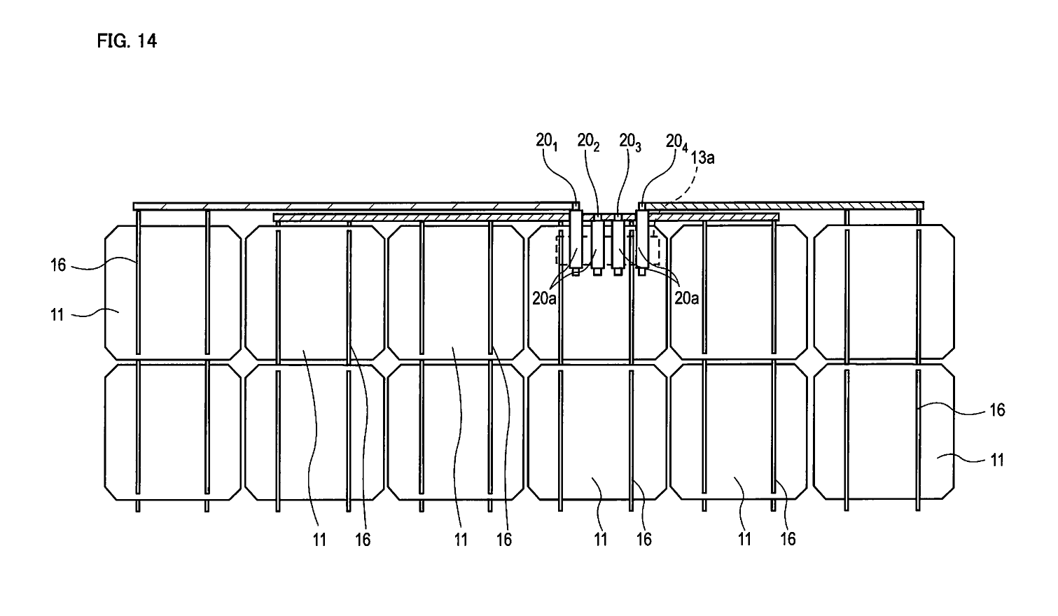

FIG. 14 is a plan view when the power output wires 20₁ through 20₄ in a solar cell module according to a fourth embodiment of the present invention which utilizes the above-described method are viewed from rear. According to the embodiment shown in this figure, three power output wires 20₁ through 20₃ are disposed between wiring members 16, 16, and one power output wires 20₄ is disposed between a wiring member 16 and an end of a solar cell 11. The arrangement makes it possible to have a distance between the wiring member 16 and the power output wires 20. This makes it possible to reduce overlapping between the wiring member 16 and the power output wires 20 even in cases where connections of the power output wires 20 are slightly misaligned. Overlapping between the power output wires 20 and the wiring member 11 increases a risk of fractured solar cell 11 during the laminating step. However, the arrangement eliminates the risk.

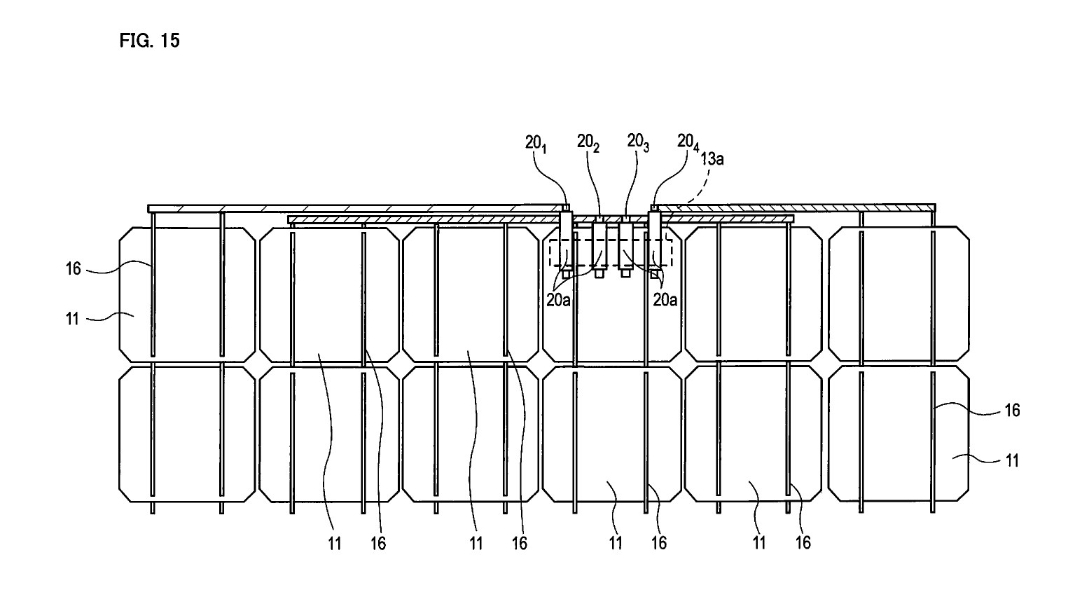

FIG. 15 is a plan view when the power output wires 20₁ through 20₄ in a solar cell module according to a fifth embodiment of the present invention which utilizes the above-described method are viewed from rear. According to the embodiment shown in this figure, two power output wires 20₂, 20₃ are disposed between wiring members 16, 16, and two power output wires 20₁, 20₄ disposed between a wiring member 16 and an end of a solar cell 11. The arrangement makes it possible to have a greater distance between the wiring member 16 and the power output wires 20 than in the fourth embodiment. This makes it possible to reduce overlapping between the wiring member 16 and the power output wires 20 even in cases where connections of the power output wires 20 are slightly misaligned. The overlapping between the power output wires 20 and the wiring member 11 increases a risk of fracturing the solar cell 11 during the laminating step. However, the arrangement eliminates the risk.

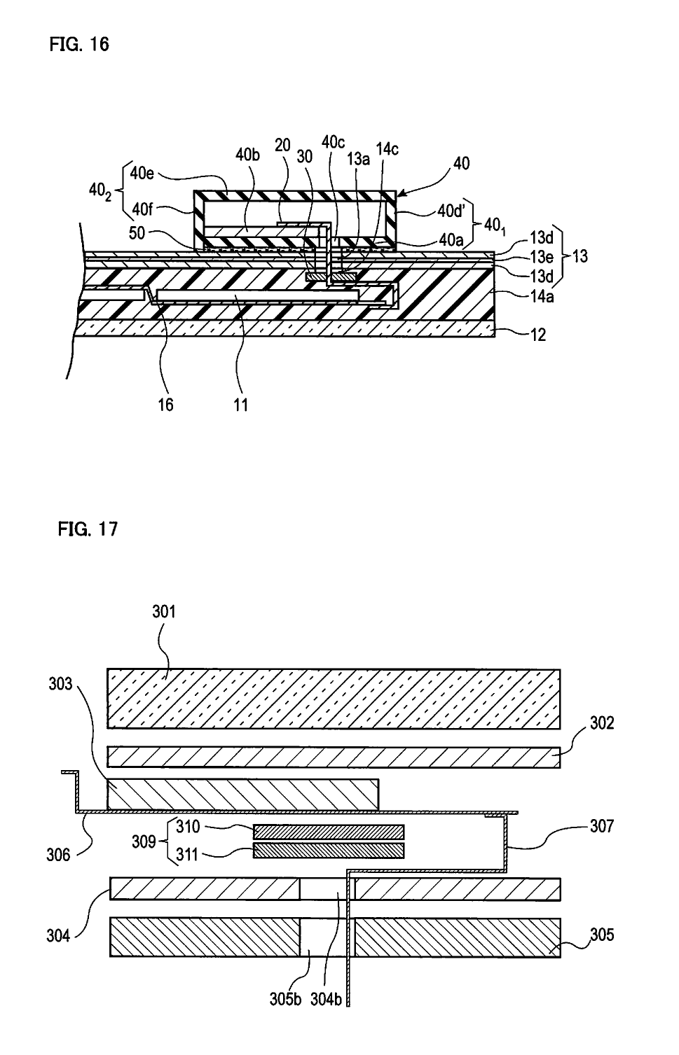

FIG. 16 is a schematic sectional view according to another embodiment.

This embodiment shown in FIG. 16 makes use of a laminated film of an Al foil 13e sandwiched between PET resin films 13d, 13d for further reduction in the amount of moisture passing through the rear-surface protection member 13. When such a laminated film is used, the rear-surface protection member 13 has a large opening 13a so that the power output wires 20 will not make contact. Here again, this opening 13a is made to face a surface of one solar cell 11. Since the opening 13a is covered by the sealing film 30, the sealing film 30 is present under the opening 13a, preventing moisture from entering. With the above, a slit 30a is made along the centerline of the opening 13a for insertion of the power output wires 20. As a result, the power output wires 20 are guided by the slit 30a, reliably separated from edges of the opening 13a, being insulated from the Al foil 13e in the rear-surface protection member 13, eliminating a risk of an electric current flowing through the Al foil 13e.

With the above-described arrangement, the bottom 40a of the terminal box 40 is bonded around the opening 13a in the rear-surface protection member 13 using a silicone resin 50 for example. The bottom 40a of the terminal box 40 has an opening 40c for insertion of the power output wires 20. This opening 40c is smaller than the openings 13a, 14c. Also, the bottom 40a is larger than the opening 13a, 14c so as to provide complete coverage over the openings 13a, 14c. Specifically, the openings 13a, 14c are larger than the opening 40c of the terminal box 40, and smaller than the terminal box 40. As another difference, the terminal box 40 shown in FIG. 5 is formed as a box, i.e., composed of a bottom 40a, a body 40d and an upper lid 41. On the other hand, the terminal box 40 shown in FIG. 16 is composed of a main body 40₁ which includes the bottom 40a and a side wall 40d′; and a lid 40₂ which includes an upper portion 40e and a side wall 40f.

The power output wires 20 coming out of the openings 13a, 14c and the opening 40c are then connected to terminals on a terminal block 40b inside the terminal box 40. Thereafter, though not illustrated, the lid 40₂ of the terminal box 40 is sealingly attached to the main body 40₁, whereby the solar cell module 10 is complete.

In all of the embodiments described above, the opening 13a is covered by the sealing film 30 which has the slit 30a; however, the sealing film 30 may be eliminated. Elimination of the sealing film 30 will decrease moisture prevention capability, but risks from the opening 13a are limited only to one solar cell 11 since the opening 13a is faced by a rear surface of one solar cell 11, and thus the arrangement can minimize influence on the performance decrease in the solar cell module 10.

Also, the sealing film 30 described thus far may be provided by a laminated film of a resin layer and an adhering member layer. In this case, the rear surface side bonding member 14b is disposed between the sealing film 30 and the solar cell 11.

The present invention is also applicable to thin film solar cell modules which use thin films of silicon and compound semiconductors.

All of the embodiments disclosed herein are to show examples, and should not be considered as of a limiting nature in any way. The scope of the present invention is identified by the claims and is not by the descriptions of the embodiments given hereabove, and it is intended that the scope includes all changes falling within equivalents in the meaning and extent of the Claims.

### REFERENCE SIGNS LIST

10 solar cell module

11 solar cell

12 front-surface protection member

13 rear-surface protection member

13a opening

14 bonding member

16 wiring member

30 sealing film

30a slit

1. A solar cell module comprising: an front-surface protection member; a rear-surface protection member; a plurality of solar cells electrically connected by wiring members and disposed between the front-surface protection member and the rear-surface protection member; a bonding member for encapsulating the solar cells between the front-surface protection member and the rear-surface protection member; and output wires for taking an output from the solar cells;
wherein the rear-surface protection member has an opening at a location facing a surface of one of the solar cells, the power output wires being routed out of the rear-surface protection member through the opening.

2. The solar cell module according to claim 1, wherein the wiring member which is connected to a light receiving surface side of one of the solar cells is connected to the wiring member which is connected to a rear surface side of an adjacent one of the solar cells by the power output wire, said power output wire being routed out of the rear-surface protection member, from a side closer to the solar cell which has the wiring member connected to the rear surface side thereof.

3. The solar cell module according to claim 1, wherein the power output wires are disposed between the wiring members of the solar cells.

4. The solar cell module according to claim 1, wherein one of the power output wires is disposed between two wiring members of the solar cells while another is disposed between a wiring member of the solar cells and an end of one of the solar cells.

5. The solar cell module according to claim 1, further comprising a sealing film disposed in a manner to cover the opening; the sealing film having a slit for insertion of the power output wires, the power output wires being routed out of the rear-surface protection member, through the slit in the sealing film and the opening.

6. The solar cell module according to claim 1, further comprising a terminal box attached to the rear-surface protection member, covering the opening in the rear-surface protection member.
